(19) United States
(12) Patent Application Publication
(10) Pub. No.: US 2025/0241100 A1
(43) Pub. Date: Jul. 24, 2025

(54) DISPLAY DEVICE AND ELECTRONIC DEVICE INCLUDING THE SAME

(71) Applicant: Samsung Electronics Co., Ltd., Suwon-si (KR)

(72) Inventors: Sunkwon Kim, Suwon-si (KR); Yongil Kwon, Suwon-si (KR); Taehyeon Kwon, Suwon-si (KR); Kangjoo Kim, Suwon-si (KR); Uijong Song, Suwon-si (KR); Jihye Yeon, Suwon-si (KR); Hyunwook Lim, Seoul (KR)

(21) Appl. No.: 19/017,041

(22) Filed: Jan. 10, 2025

(30) Foreign Application Priority Data
Jan. 19, 2024 (KR) 10-2024-0008634
Apr. 25, 2024 (KR) 10-2024-0055576

(51) Int. Cl. H10H 29/34

(52) U.S. Cl. CPC H10H 29/34

(57) ABSTRACT

A display device includes a backplane including a first pixel array region, a second pixel array region, a third pixel array region, and a peripheral circuit region, a first pixel array arranged on the first pixel array region, a first pixel circuit unit arranged on the first pixel array region and configured to drive the first pixel array, a second pixel array arranged on the second pixel array region, a second pixel circuit unit arranged on the second pixel array region and configured to drive the second pixel array, a third pixel array arranged on the third pixel array region, a third pixel circuit unit arranged on the third pixel array region and configured to drive the third pixel array, and a drive circuit unit arranged on the peripheral circuit region.

### CROSS-REFERENCE TO RELATED APPLICATIONS

This application is based on and claims priority under 35 U.S.C. § 119 to Korean Patent Application Nos. 10-2024-0008634, filed on Jan. 19, 2024 and 10-2024-0055576, filed on Apr. 25, 2024, in the Korean Intellectual Property Office, the disclosures of which are incorporated by reference herein in their entirety.

### BACKGROUND

The inventive concept relates to a display device and an electronic device including the same, and more particularly, to a display device including a pixel having a small area and an electronic device including the display device.

As the information society develops, the demand for display devices that display images is increasing, and various types of display devices, such as liquid crystal display devices, plasma display devices, and organic light-emitting display devices, are being used. In particular, interest in display devices using micro light-emitting diodes has recently been increasing.

As display device characteristics are required to be improved to implement virtual reality (VR), augmented reality (AR), or mixed reality technology, methods of integrating micro light-emitting diode pixel arrays or organic micro light-emitting diode arrays on a silicon substrate have been proposed. In particular, the demand for minimizing a pixel size is increasing to produce high-resolution images.

### SUMMARY

Aspects of the inventive concept provide a display device having a small pixel size and capable of low-power operation and an electronic device including the same.

According to an aspect of the inventive concept, a display device includes a backplane including a first pixel array region, a second pixel array region, a third pixel array region, and a peripheral circuit region, each region horizontally separate from each other region, a first pixel array arranged on the first pixel array region of the backplane, a first pixel circuit unit arranged on the first pixel array region of the backplane and configured to drive the first pixel array, a second pixel array arranged on the second pixel array region of the backplane, a second pixel circuit unit arranged on the second pixel array region of the backplane and configured to drive the second pixel array, a third pixel array arranged on the third pixel array region of the backplane, a third pixel circuit unit arranged on the third pixel array region of the backplane and configured to drive the third pixel array, and a drive circuit unit arranged on the peripheral circuit region of the backplane.

According to another aspect of the inventive concept, a display device includes a backplane including a first pixel array region, a second pixel array region, a third pixel array region, and a peripheral circuit region, a first pixel array arranged on the first pixel array region of the backplane and including a plurality of first light-emitting elements arranged in a matrix, a second pixel array arranged on the second pixel array region of the backplane and including a plurality of second light-emitting elements arranged in a matrix, a third pixel array arranged on the third pixel array region of the backplane and including a plurality of third light-emitting elements arranged in a matrix, and a drive circuit unit arranged on the peripheral circuit region of the backplane, wherein the drive circuit unit includes a receiver interface configured to receive image data and a control signal from an external host and a drive circuit configured to drive the first pixel array, the second pixel array, and the third pixel array, based on the image data and the control signal.

According to a further aspect of the inventive concept, an electronic device includes a host processor and a display system connected to the host processor, wherein the display system includes a backplane including a first pixel array region, a second pixel array region, a third pixel array region, and a peripheral circuit region, a first pixel array arranged on the first pixel array region of the backplane and including a plurality of first light-emitting elements arranged in a matrix, a second pixel array arranged on the second pixel array region of the backplane and including a plurality of second light-emitting elements arranged in a matrix, a third pixel array arranged on the third pixel array region of the backplane and including a plurality of third light-emitting elements arranged in a matrix, and a drive circuit unit arranged on the peripheral circuit region of the backplane, wherein the drive circuit unit includes a receiver interface configured to receive image data and a control signal from the host processor and a drive circuit configured to drive the first pixel array, the second pixel array, and the third pixel array, based on the image data and the control signal.

### BRIEF DESCRIPTION OF THE DRAWINGS

Embodiments will be more clearly understood from the following detailed description taken in conjunction with the accompanying drawings in which:

FIG. 1 is a schematic diagram of a display device according to embodiments;

FIG. 2 is a schematic diagram of an electronic device including the display device of FIG. 1, according to embodiments;

FIG. 3 is a schematic diagram of a pixel array of a display device, according to embodiments;

FIG. 4A is a schematic diagram of a light-emitting element included in a display device, according to embodiments;

FIG. 4B is a schematic diagram of a light-emitting element included in a display device, according to embodiments;

FIG. 5 is a schematic diagram of a light-emitting element according to embodiments;

FIG. 6 is a schematic diagram of a display device according to embodiments;

FIG. 7 is a schematic diagram of a display device according to embodiments;

FIG. 8 is a schematic diagram of a display device according to embodiments;

FIG. 9 is a schematic diagram of a display device according to embodiments;

FIG. 10 is a schematic diagram of a display device according to embodiments;

FIG. 11 is a flowchart of a method of manufacturing a display device, according to embodiments;

FIGS. 12A to 12H are schematic diagrams illustrating a method of manufacturing a display device, according to embodiments;

FIGS. 13A and 13B are schematic diagrams of a head-mounted display using a display device according to embodiments;

FIG. 14 is a schematic diagram of an example of a display-accommodating case in FIGS. 13A and 13B; and

FIG. 15 is a schematic diagram of another example of the display-accommodating case in FIGS. 13A and 13B.

### DETAILED DESCRIPTION OF THE EMBODIMENTS

Hereinafter, embodiments are described with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Hereinafter, embodiments in the example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

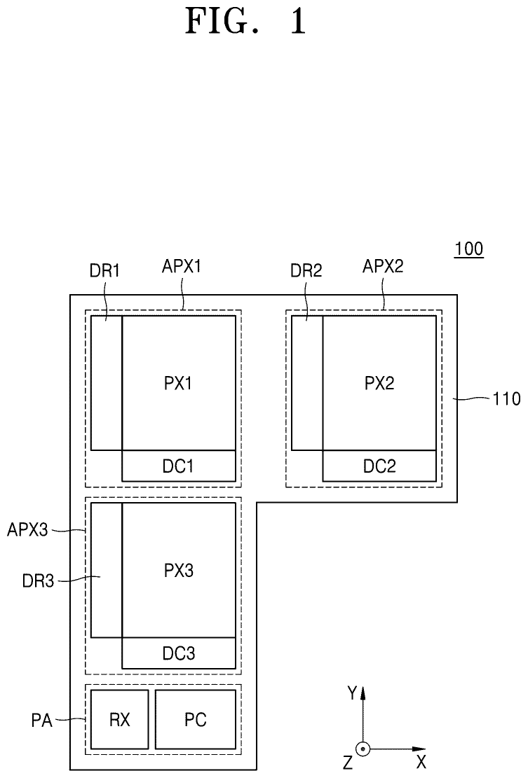

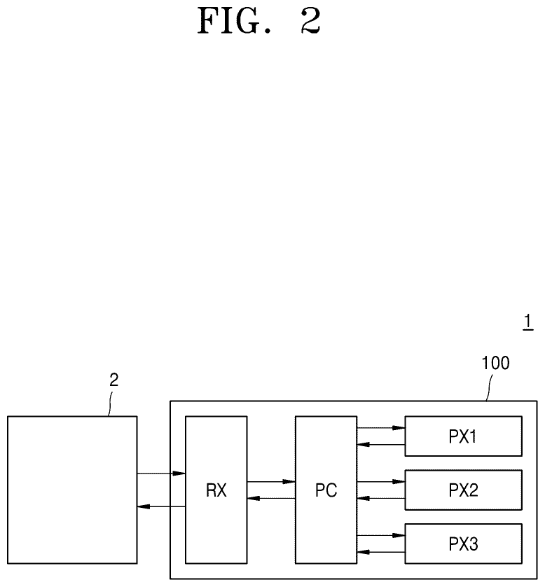

FIG. 1 is a schematic diagram of a display device 100 according to embodiments. FIG. 2 is a schematic diagram of an electronic device 1 including the display device 100 of FIG. 1, according to embodiments.

Referring to FIGS. 1 and 2, the display device 100 may be mounted on the electronic device 1 having an image display function. For example, the electronic device 1 having an image display function may include an electronic device using a virtual reality system. For example, the virtual reality system may allow users to experience virtual reality and may include an electronic device for implementing virtual reality (VR), augmented reality (AR), or mixed reality (MR) technology. For example, the display device 100 may be mounted on a wearable device, such as a head-up device or VR glasses, to provide high-resolution images for displaying VR content to a user.

According to some embodiments, the electronic device 1 having an image display function may be or include at least one selected from the group consisting of a smartphone, a tablet personal computer (PC), a mobile phone, a video phone, an e-book reader, a desktop PC, a laptop PC, a netbook computer, a personal digital assistant (PDA), a portable multimedia player (PMP), an MP3 player, a mobile medical device, a camera, electronic clothing, an electronic bracelet, an electronic necklace, an electronic appcessory, an electronic tattoo, and a smart watch.

According to some embodiments, the electronic device 1 may include a smart home appliance having an image display function. For example, the smart home appliance may include at least one selected from the group consisting of a television (TV), a digital video disk (DVD) player, an audio player, a refrigerator, an air conditioner, a vacuum cleaner, an oven, a microwave, a washing machine, an air cleaner, a set-top box, a TV box, a game console, an electronic dictionary, an electronic key, a camcorder, and an electronic picture frame.

According to some embodiment, the electronic device 1 may include at least one selected from the group consisting of various medical devices (e.g., a magnetic resonance angiography (MRA) apparatus, a magnetic resonance imaging (MRI) apparatus, a computed tomography (CT) scanner, an imaging machine, and a sonograph), a navigation device, a global positioning system (GPS) receiver, an event data recorder (EDR), a flight data recorder (FDR), an automobile infotainment device, electronic equipment for ships (e.g., navigation equipment for ships and a gyrocompass), avionics, security equipment, an automobile head unit, an industrial robot, a home robot, an automatic teller's machine (ATM), and a point-of-sale (POS) system.

According to some embodiments, the electronic device 1 may include at least one selected from the group consisting of furniture having an image display function, a portion of a building or structure having an image display function, an electronic board, an electronic signature-receiving device, a projector, and various measuring instruments (e.g., a water meter, an electricity meter, a gas meter, and a radio wave measuring device). According to embodiments, the electronic device 1 may include one of the various devices described above or a combination thereof. The electronic device 1 may include a flexible display device.

According to embodiments, the display device 100 may include a backplane 110. The backplane 110 may include a first pixel array region APX1, a second pixel array region APX2, a third pixel array region APX3, and a peripheral circuit region PA.

In embodiments, the backplane 110 may include or be formed of a semiconductor substrate, such as a silicon substrate, a germanium substrate, or a silicon germanium substrate, or a silicon-on-insulator (SOI) substrate. From a thickness or vertical perspective, the backplane 110 may be at an opposite surface of the display device 100 from a surface that radiates light. In embodiments, the backplane 110 may be provided with a wiring line and a via structure, which are arranged on or above the top surface of the backplane 110. The backplane 110 may be provided with a through via structure that at least partially extends to the inside of the backplane 110. The wiring line, the via structure, and the through via structure may be provided in various forms for electrical connections between various drive circuits arranged on the backplane 110. In some descriptions, the backplane may refer to a backplane substrate on which other components are formed. In some descriptions, the backplane may refer to a combination of the backplane substrate and the wiring line, via structure, and through via structure.

In embodiments, the display device 100 may include a drive circuit unit in the peripheral circuit region PA of the backplane 110. The drive circuit unit may include various kinds of circuits to drive first to third pixel arrays PX1, PX2, and PX3. In embodiments, the drive circuit unit may include a receiver interface RX and a drive circuit PC. Each of the receiver interface RX and the driver circuit PC may be formed in an uninterrupted area of the display device. For example, the receiver interface RX may not have separate sections separated by one or more pixel arrays, and the driver circuit PC may not have separate sections separated by one or more pixel arrays.

In embodiments, as illustrated in FIG. 2, the receiver interface RX may be configured to receive image data and a control signal from an external host (or a host processor) 2. In embodiments, the receiver interface RX may include a central processing unit (CPU) interface, a red, green, and blue (RGB) interface, a mobile industry processor interface (MIPI), a mobile display digital interface (MDDI), a compact display port (CDP) interface, a mobile pixel link (MPL) interface, a current mode advanced differential signaling (CMADS) interface, a serial peripheral interface (SPI), an inter-integrated circuit (I2C) interface, a DisplayPort (DP) interface, or an embedded DP (eDP) interface. Besides those above, the receiver interface RX may include one of other high-speed serial interfaces.

In embodiments, as illustrated in FIG. 2, the drive circuit PC may generate an image signal by processing image data based on a control signal transmitted from the receiver interface RX and may transmit the image signal to the first to third pixel arrays PX1, PX2, and PX3 respectively arranged in the first to third pixel array regions APX1, APX2, and APX3. In embodiments, the drive circuit PC, also described as a display device driver circuit, may include a memory controller, graphics memory, a shift register controller, a shift register, a source driver, and/or the like.

For example, the memory controller may control an operation of writing data to the graphics memory and an operation of reading data from the graphics memory, based on image data and a control signal, which are transmitted from the receiver interface RX. For example, the graphics memory may store or output data under control by the memory controller. For example, the shift register controller may control the operation of the shift register and provide data from the graphics memory to the shift register. For example, the shift register may shift line data or transmit the line data to the source driver, under control by the shift register controller. The source driver may drive the first to third pixel arrays PX1, PX2, and PX3 based on line data transmitted from the shift register.

In embodiments, a connection terminal such as a pad may be arranged in the peripheral circuit region PA. A connection member such as a connector pin may be arranged on the pad, and accordingly, the display device 100 may be electrically connected to the external host 2.

In embodiments, as illustrated in FIG. 1, the first to third pixel array regions APX1, APX2, and APX3 may be arranged on the top surface of the backplane 110 in a planar fashion. For example, the second pixel array region APX2 may be adjacent to the first pixel array region APX1 in a first horizontal direction X. For example, the first and second pixel array regions APX1 and APX2 may be side by side in the first horizontal direction X. The third pixel array region APX3 may be adjacent to the first pixel array region APX1 in a second horizontal direction Y that crosses the first horizontal direction X. For example, the first and third pixel array regions APX1 and APX3 may be arranged side by side in the second horizontal direction Y.

The arrangement of the first to third pixel array regions APX1, APX2, and APX3 is not limited to that illustrated in FIG. 1. In some embodiments, the first to third pixel array regions APX1, APX2, and APX3 may be arranged in a straight line in the first horizontal direction X or the second horizontal direction Y. In some embodiments, the first to third pixel array regions APX1, APX2, and APX3 may be arranged offset in the first horizontal direction X or the second horizontal direction Y or arranged in a zigzag pattern.

In embodiments, the first to third pixel arrays PX1, PX2, and PX3 may be respectively mounted on the first to third pixel array regions APX1, APX2, and APX3. For example, the first to third pixel arrays PX1, PX2, and PX3 may emit light of different colors from each other.

In embodiments, the first pixel array PX1 may include a pixel matrix emitting red light. For example, the pixel matrix may include a plurality of first light-emitting elements arranged in a matrix. For example, the first light-emitting elements may be configured to emit light in a range of about 570 nm to about 750 nm.

In embodiments, the second pixel array PX2 may include a pixel matrix emitting green light. For example, the pixel matrix may include a plurality of second light-emitting elements arranged in a matrix. For example, the second light-emitting elements may be configured to emit light in a range of about 495 nm to about 570 nm.

In embodiments, the third pixel array PX3 may include a pixel matrix emitting blue light. For example, the pixel matrix may include a plurality of third light-emitting elements arranged in a matrix. For example, the third light-emitting elements may be configured to emit light in a range of about 415 nm to about 495 nm.

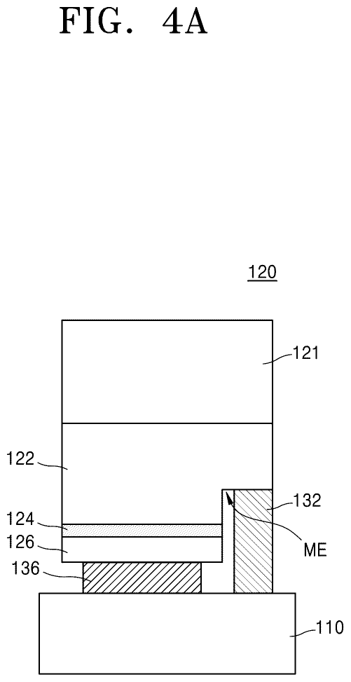

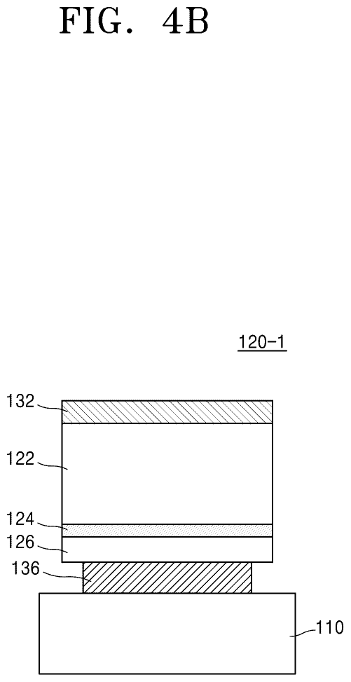

In embodiments, the first to third light-emitting elements may include micro light-emitting diodes. A micro light-emitting diode may refer to a light-emitting diode having a relatively small size, for example, a size of 50 micrometers or less, 30 micrometers or less, 10 micrometers or less, 5 micrometers or less, 3 micrometers or less, or 2 micrometers or less. The detailed configuration of the first to third light-emitting elements is described with reference to FIG. 4A below.

In embodiments, a first pixel circuit unit may be arranged in or on the first pixel array region APX1 of the backplane 110. The first pixel circuit unit may include various circuits to drive the first pixel array PX1. For example, the first pixel circuit unit may include various circuits to drive the first pixel array PX1 in passive mode or active mode.

In embodiments, the first pixel circuit unit, also described as a pixel driver circuit, may include a first row driver DR1 connected to row lines of the first pixel array PX1. For example, the first row driver DR1 may generate control signals for sequentially driving a plurality of rows in the first pixel array PX1 and may transmit the control signals to the first pixel array PX1. For example, a row line may refer to a wiring line extending in the first horizontal direction X and may be connected in common to a plurality of pixels of the first pixel array PX1, which are arranged in a line in the first horizontal direction X.

In embodiments, the first pixel circuit unit may include a first column driver DC1 connected to column lines of the first pixel array PX1. For example, the first column driver DC1 may generate control signals for sequentially driving a plurality of columns in the first pixel array PX1 and may transmit the control signals to the first pixel array PX1. For example, a column line may refer to a wiring line extending in the second horizontal direction Y and may be connected in common to a plurality of pixels of the first pixel array PX1, which are arranged in a line in the second horizontal direction Y.

In embodiments, the first pixel array PX1 may further include shift registers connected to the first light-emitting elements, respectively. Each of the shift registers may be configured to output a pulse width modulation (PWM) signal, which has an adjusted width to adjust the brightness of a first light-emitting element. The first pixel array PX1 may further include a transistor (e.g., a switch) configured to transmit or block a driving current to the first light-emitting element according to the PWM signal transmitted from the shift register.

In embodiments, transistors of each first pixel circuit unit, shift register, or switch may be or include complementary metal-oxide semiconductor (CMOS) transistors. In some embodiments, transistors of each first pixel circuit unit, shift register, or switch may be or include a thin film transistor.

In embodiments, a second pixel circuit unit may be arranged in or on the second pixel array region APX2 of the backplane 110. The second pixel circuit unit may include various circuits to drive the second pixel array PX2. For example, the second pixel circuit unit may include various circuits to drive the second pixel array PX2 in passive mode or active mode. In embodiments, the second pixel circuit unit may include a second row driver DR2 connected to row lines of the second pixel array PX1. In embodiments, the second pixel circuit unit may include a second column driver DC2 connected to column lines of the second pixel array PX2.

In embodiments, the second pixel array PX2 may further include shift registers connected to the second light-emitting elements, respectively, or a transistor (e.g., a switch) configured to transmit or block a driving current to one of the second light-emitting elements according to a PWM signal transmitted from one of the shift registers.

In embodiments, a third pixel circuit unit may be arranged in or on the third pixel array region APX3 of the backplane 110. The third pixel circuit unit may include various circuits to drive the third pixel array PX3. For example, the third pixel circuit unit may include various circuits to drive the third pixel array PX3 in passive mode or active mode. In embodiments, the third pixel circuit unit may include a third row driver DR3 connected to row lines of the third pixel array PX3. In embodiments, the third pixel circuit unit may include a third column driver DC3 connected to column lines of the third pixel array PX3.

In embodiments, the third pixel array PX3 may further include shift registers connected to the third light-emitting elements, respectively, or a transistor (e.g., a switch) configured to transmit or block a driving current to one of the third light-emitting elements according to a PWM signal transmitted from one of the shift registers.

According to embodiments, the first pixel circuit unit in the first pixel array region APX1 may be connected to the drive circuit unit through a wiring structure. The wiring structure may include wiring lines, contacts, conductive vias, through via structures, or a combination thereof. The second pixel circuit unit in the second pixel array region APX2 may be connected to the drive circuit unit through a wiring structure. The wiring structure may include wiring lines, contacts, conductive vias, through via structures, or a combination thereof. The third pixel circuit unit in the third pixel array region APX3 may be connected to the drive circuit unit through a wiring structure. The wiring structure may include wiring lines, contacts, conductive vias, through via structures, or a combination thereof. Each wiring structure may be formed before or after the plurality of first to third light-emitting elements are integrated in the backplane 110.

As the first to third pixel arrays PX1, PX2, and PX3 are electrically connected to the drive circuit PC through the wiring structure, only one receiver interface RX may be arranged in or on the backplane 110. For example, for the exchange of image data and control signals between the external host 2 and the display device 100, the display device 100 may include only one receiver interface RX.

In a display device according to a comparative example, only a display driving circuit may be formed in a backplane die, and a first die including a red pixel array, a second die including a green pixel array, and a third die including a blue pixel array may be electrically connected to the backplane die. To integrate the backplane die with the first to third dies, a complex package structure, such as a redistribution structure or a fan-out structure, is typically required. To exchange image data and control signals with the backplane die, each of the first to third dies needs to include a receiver interface and/or a transmitter interface. However, a circuit device for an interface consumes relatively high power and occupies a relatively large area. In addition, tolerance or an alignment margin occurs in a process of connecting the first to third dies to the backplane die or a process of assembling a lens in a position corresponding to each of the first to third dies, and thus, the cumulative tolerance of the entire display device relatively increases.

However, according to embodiments, as the first to third pixel arrays PX1, PX2, and PX3 and a drive circuit unit may be arranged in the backplane 110 and the first to third pixel arrays PX1, PX2, and PX3 may be connected to the drive circuit PC through a wiring structure, only one receiver interface RX may be arranged in or on the backplane 110. Accordingly, the display device 100 may be capable of low-power operation and may have a compact size. In addition, because a package structure requiring a complex process for connecting a plurality of dies is unnecessary, the manufacturing process of the display device 100 may be simplified. Furthermore, because cumulative tolerance that may occur when a plurality of dies are connected or cumulative tolerance between a die and a lens is reduced, the display device 100 may have a relatively small tolerance.

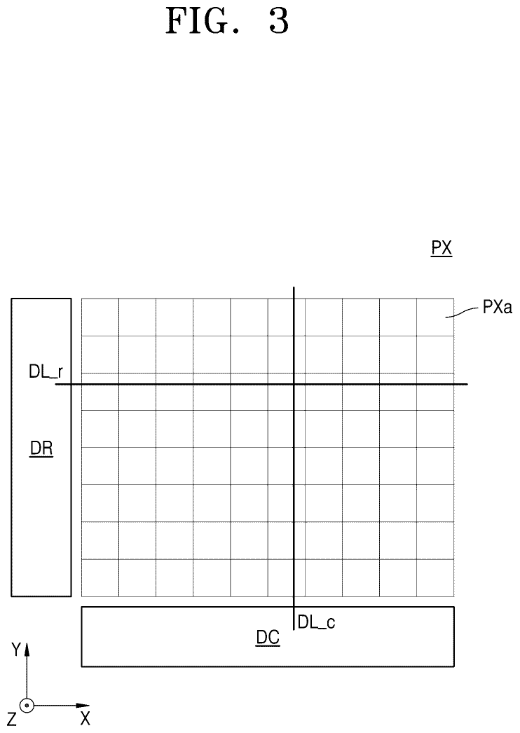

FIG. 3 is a schematic diagram of a pixel array PX of a display device, according to embodiments.

Referring to FIG. 3, the pixel array PX may include a plurality of pixels PXa arranged in a matrix. The pixels PXa may be arranged in the first horizontal direction X and the second horizontal direction Y. For example, the number of pixels PXa arranged in the first horizontal direction X and the number of pixels PXa arranged in the second horizontal direction Y are not limited to those in FIG. 3.

For example, a row driver DR may be arranged at one side of the pixel array PX in the first horizontal direction X. The row driver DR may include a plurality of driver circuits, each connected to a respective row line DL_r and connected in common to a plurality of pixels PXa, which are arranged in the first horizontal direction X, through the row line DL_r.

A column driver DC may be arranged at one side of the pixel array PX in the second horizontal direction Y. The column driver DC may include a plurality of driver circuits, each connected to a respective column line DL_c and connected in common to a plurality of pixels PXa, which are arranged in the second horizontal direction Y, through the column line DL_c.

In embodiments, the pixel array PX may include one of the first to third pixel arrays PX1, PX2, and PX3 described with reference to FIG. 1.

In embodiments, the plurality of pixels PXa constituting the pixel array PX may emit light representing one color. For example, the pixels PXa constituting the first pixel array PX1 may include a first light-emitting element emitting red light. For example, the pixels PXa constituting the second pixel array PX2 may include a second light-emitting element emitting green light. For example, the pixels PXa constituting the third pixel array PX3 may include a third light-emitting element emitting blue light.

In some embodiments, the pixels PXa constituting each pixel array PX may emit light representing different colors. For example, each pixel array PX (e.g., one or more of the first pixel array PX1, second pixel array PX2, or third pixel array PX3) may have an array of pixels PXa forming a Bayer pattern and may include a plurality of 2×2 sub arrays constituted of four light-emitting elements respectively emitting red light, green light, green light, and blue light.

FIG. 4A is a schematic diagram of a light-emitting element 120 included in a display device, according to embodiments.

Referring to FIG. 4A, the light-emitting element 120 may include a substrate 121, a first conductivity-type semiconductor layer 122, an active layer 124, and a second conductivity-type semiconductor layer 126.

The substrate 121 may be a transparent substrate such as sapphire. The substrate 121 may include a light-emitting surface adjacent to the light-emitting element 120. For example, light having a particular wavelength may be emitted upward from the light-emitting element 120 through the substrate 121.

The first conductivity-type semiconductor layer 122 may be or may include a p-type semiconductor layer. For example, the first conductivity-type semiconductor layer 122 may be formed of or may include at least one selected from GaN, AlGaN, AlInP, GaInP, AlGaInP, AlP, GaP, and InP, each doped with p-type impurities. The first conductivity-type semiconductor layer 122 may include a p-type dopant, which may include or be at least one selected from magnesium, zinc, calcium, selenium, and barium.

In some embodiments, the second conductivity-type semiconductor layer 126 may be formed of or may include at least one selected from AlGaInP, AlGaN, AlInGaN, GaN, GaAs, and InGaAs, each doped with n-type impurities. The second conductivity-type semiconductor layer 126 may include an n-type dopant, which may include or be silicon.

In embodiments, the active layer 124 may have a multi-quantum well (MQW) structure in which a quantum well layer and a quantum barrier layer are alternately stacked. For example, the quantum well layer and the quantum barrier layer may include InₓAl_{y}Ga_{(1-x-y)}N (0≤x, y≤1, 0≤x+y≤1) having different compositions. For example, the quantum well layer may include InₓGa₁₋ₓN (0≤x≤1) and the quantum barrier layer may include GaN or AlGaN. In some embodiments, the active layer 124 may have a single quantum well structure.

The light-emitting element 120 may include a mesa region ME, which may be obtained by partially removing the first conductivity-type semiconductor layer 122 and exposing a portion of the top surface of the second conductivity-type semiconductor layer 126 in a mesa etching process.

A first electrode 132 may be arranged on the bottom surface of the first conductivity-type semiconductor layer 122. A second electrode 136 may be arranged on the bottom surface of the second conductivity-type semiconductor layer 126. The first electrode 132 may include or be formed of at least one selected from Ag, Ni, Al, Cr, Rh, Pd, Ir, Ru, Mg, Zn, Pt, and Au. The second electrode 136 may have a reflective electrode structure. The second electrode 136 may include or be formed of at least one selected from Ag, Ni, Al, Cr, Rh, Pd, Ir, Ru, Mg, Zn, Pt, and Au. In some embodiments, the second electrode 136 may have a double-layer structure, such as Ni/Ag, Zn/Ag, Ni/Al, Zn/Al, Pd/Ag, Pd/Al, Ir/Ag, Ir/Au, Pt/Al, or Pt/Ag.

The first electrode 132 and the second electrode 136 may be arranged in a lower portion of the light-emitting element 120. The light-emitting element 120 may be attached to the backplane 110 in a flip-chip manner by using the first electrode 132 and the second electrode 136. The first electrode 132 and the second electrode 136 may be mounted in a flip-chip manner on a wiring pattern, which is provided in an upper portion of the backplane 110, by using a bump, for example, including Au, Sn, Cu, In, an alloy thereof, or a combination thereof.

In some embodiments, a rugged portion or a protrusion may be arranged between the substrate 121 and the first conductivity-type semiconductor layer 122. In some embodiments, the substrate 121 may be omitted. In this case, the first conductivity-type semiconductor layer 122 may act as a light-emitting surface of the light-emitting element 120.

In some embodiments, the light-emitting element 120 may be a blue light-emitting element that emits light having a peak intensity in a blue wavelength range (e.g., about 415 nm to about 495 nm). A wavelength converter may be further arranged in an upper portion of the light-emitting element 120. The wavelength converter may include a fluorescent material capable of converting the wavelength of light emitted from the light-emitting element 120. The fluorescent material may have various compositions and colors, like an oxide-based material, a silicate-based material, a nitride-based material, a fluorite-based material, or the like. In some embodiments, the wavelength converter may include quantum dots.

Although an embodiment, in which the light-emitting element 120 includes a light-emitting diode based on an inorganic material, has been described with reference to FIG. 4A, the light-emitting element 120 may include a light-emitting diode based on an organic material in some embodiments. For example, the light-emitting element 120 may include an organic pixel stack of an anode electrode, an organic material layer, and a cathode electrode. The organic material layer in the organic pixel stack may have a stack structure including a hole injection layer, a hole transfer layer, an organic light-emitting layer, an electron transfer layer, and an electron injection layer.

FIG. 4B is a schematic diagram of a light-emitting element 120-1 included in a display device, according to embodiments.

Referring to FIG. 4B, the light-emitting element 120-1 may have a vertical structure. The substrate 121 and the mesa region ME of the light-emitting element 120, which have been described with reference to FIG. 4A, may be omitted from the light-emitting element 120-1. The first electrode 132 may be arranged on the top surface of the first conductivity-type semiconductor layer 122 and the second electrode 136 may be arranged on the bottom surface of the second conductivity-type semiconductor layer 126, and accordingly, the first conductivity-type semiconductor layer 122, the active layer 124, and the second conductivity-type semiconductor layer 126 are sequentially arranged between the first electrode 132 and the second electrode 136 in the vertical direction.

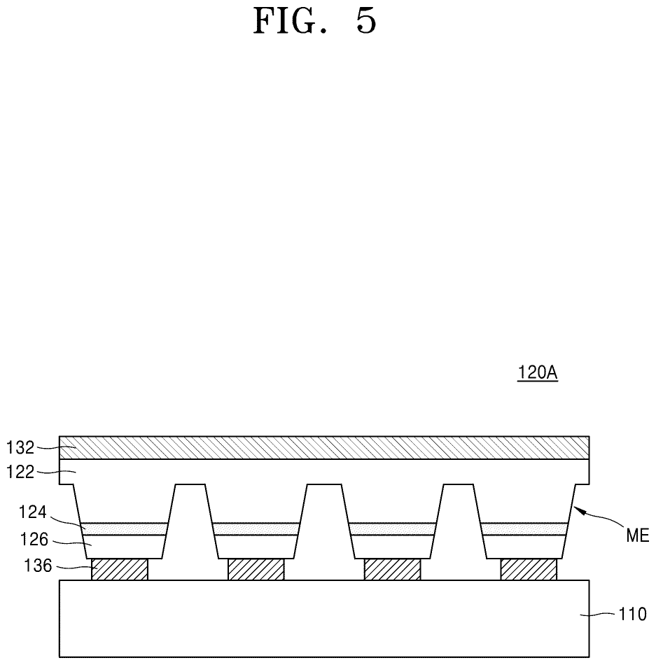

FIG. 5 is a schematic diagram of a light-emitting element 120A according to embodiments.

Referring to FIG. 5, the light-emitting element 120A may have a vertical structure, in which a portion of the first conductivity-type semiconductor layer 122 is not removed, such that a plurality of first conductivity-type semiconductor layers 122 are connected to each other. For example, one light-emitting element 120A may be defined by a mesa region ME, respective first conductivity-type semiconductor layers 122 of a plurality of light-emitting elements 120A may be connected to each other, and the first electrode 132 may extend on the top surfaces of the first conductivity-type semiconductor layers 122 in a horizontal direction and overlap all the light-emitting elements 120A.

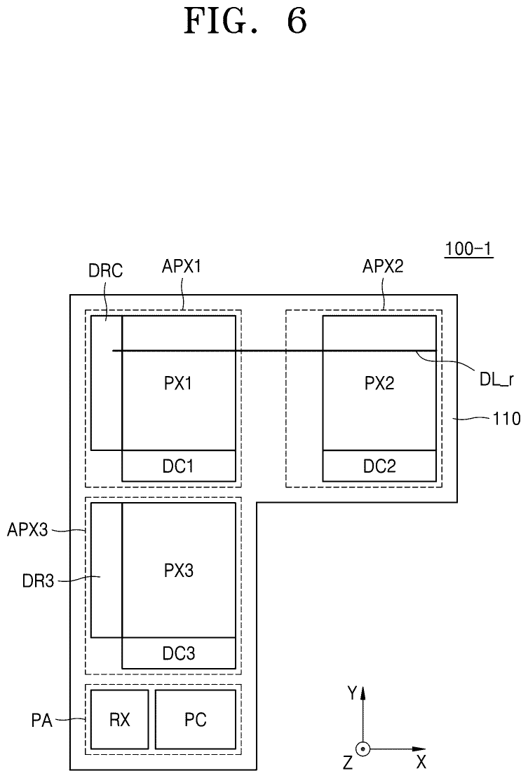

FIG. 6 is a schematic diagram of a display device 100-1 according to embodiments.

Referring to FIG. 6, the second pixel array region APX2 may be adjacent to the first pixel array region APX1 in the first horizontal direction X. Therefore, the first and second pixel array regions APX1 and APX2 may be side by side in the first horizontal direction X. The third pixel array region APX3 may be adjacent to the first pixel array region APX1 in the second horizontal direction Y that crosses the first horizontal direction X. Therefore, the first and third pixel array regions APX1 and APX3 may be arranged side by side in the second horizontal direction Y.

In embodiments, the row line DL_r may be connected in common to the first pixel array PX1 and the second pixel array PX2. A first pixel circuit unit may include a common row driver DRC including a plurality of driver circuits electrically connected to respective row lines DL_r, each row line DL_r which is connected in common to a row of the first pixel array PX1 and a row of the second pixel array PX2.

In embodiments, the first pixel array PX1 and the second pixel array PX2 may be controlled by the common row driver DRC, and accordingly, the second row driver DR2 (see FIG. 1) may be omitted, thereby reducing the size of the display device 100-1. In addition, because the first pixel array PX1 and the second pixel array PX2 are controlled by the common row driver DRC, a separate circuit device for timing control of the first pixel array PX1 and the second pixel array PX2 may be omitted. Accordingly, the image quality of the display device 100-1 may be increased.

Although it is illustrated in FIG. 6 that the first pixel circuit unit includes the common row driver DRC, which is arranged in the first pixel array region APX1, alternatively, the second pixel circuit unit may include the common row driver DRC, which is arranged in the second pixel array region APX2, in some embodiments.

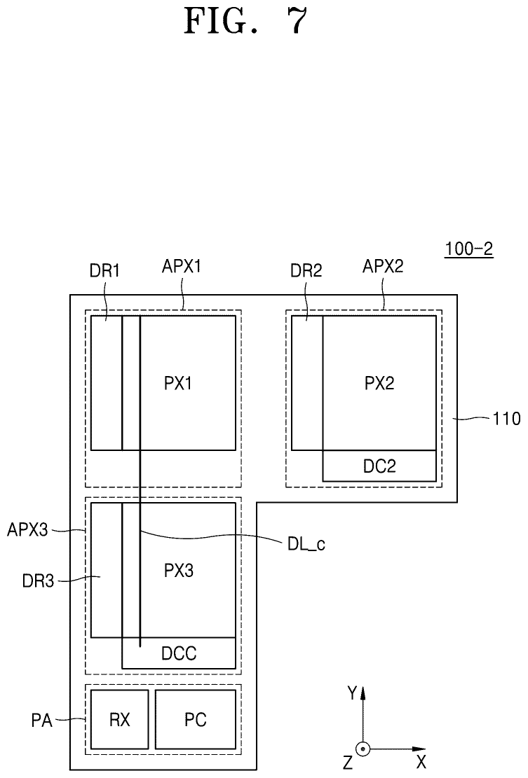

FIG. 7 is a schematic diagram of a display device 100-2 according to embodiments.

Referring to FIG. 7, the second pixel array region APX2 may be adjacent to the first pixel array region APX1 in the first horizontal direction X, and the third pixel array region APX3 may be adjacent to the first pixel array region APX1 in the second horizontal direction Y that crosses the first horizontal direction X.

In embodiments, the column line DL_c may be connected in common to the first pixel array PX1 and the third pixel array PX3. A third pixel circuit unit may include a common column driver DCC electrically connected to the column lines DL_c, which are each connected in common to the first pixel array PX1 and the third pixel array PX3.

In embodiments, the first pixel array PX1 and the third pixel array PX3 may be controlled by the common column driver DCC, and accordingly, the first column driver DC1 (see FIG. 1) may be omitted, thereby reducing the size of the display device 100-2. In addition, because the first pixel array PX1 and the third pixel array PX3 are controlled by the common column driver DCC, a separate circuit device for timing control of the first pixel array PX1 and the third pixel array PX3 may be omitted. Accordingly, the image quality of the display device 100-2 may be increased.

Although it is illustrated in FIG. 7 that the third pixel circuit unit includes the common column driver DCC, which is arranged in the third pixel array region APX3, alternatively, the first pixel circuit unit may include the common column driver DCC, which is arranged in the first pixel array region APX1, in some embodiments.

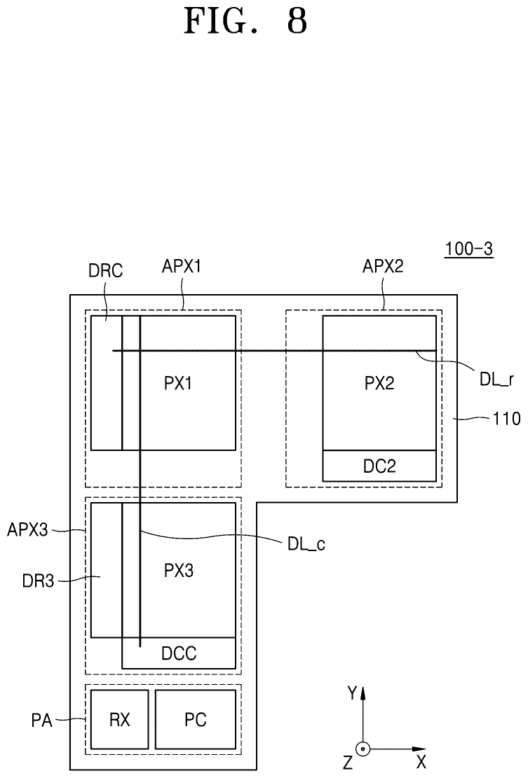

FIG. 8 is a schematic diagram of a display device 100-3 according to embodiments.

Referring to FIG. 8, the row line DL_r may be connected in common to the first pixel array PX1 and the second pixel array PX2. The column line DL_c may be connected in common to the first pixel array PX1 and the third pixel array PX3.

A first pixel circuit unit may include the common row driver DRC electrically connected to the row line DL_r, which is connected in common to the first pixel array PX1 and the second pixel array PX2. A third pixel circuit unit may include the common column driver DCC electrically connected to the column line DL_c, which is connected in common to the first pixel array PX1 and the third pixel array PX3.

In embodiments, the first pixel array PX1 and the second pixel array PX2 may be controlled by the common row driver DRC, and the first pixel array PX1 and the third pixel array PX3 may be controlled by the common column driver DCC.

According to embodiments, as the common row driver DRC and the common column driver DCC are provided, the size of the display device 100-3 may be reduced. In addition, because the first to third pixel arrays PX1, PX2, and PX3 are simultaneously controlled by the common row driver DRC and the common column driver DCC, a separate circuit device for timing control of each of the first to third pixel arrays PX1, PX2, and PX3 may be omitted. Accordingly, the image quality of the display device 100-3 may be increased

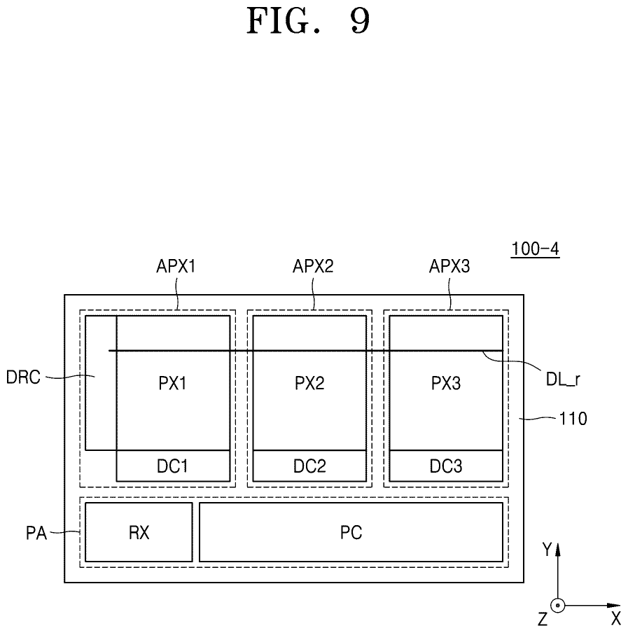

FIG. 9 is a schematic diagram of a display device 100-4 according to embodiments.

Referring to FIG. 9, the first pixel array region APX1, the second pixel array region APX2, and the third pixel array region APX3 may be arranged in line in the first horizontal direction X. For example, the second pixel array region APX2 may be arranged between the first pixel array region APX1 and the third pixel array region APX3.

The row line DL_r may be connected in common to the first pixel array PX1, the second pixel array PX2, and the third pixel array PX3. A first pixel circuit unit may include the common row driver DRC electrically connected to the row line DL_r, which is connected in common to the first pixel array PX1, the second pixel array PX2, and the third pixel array PX3.

According to embodiments, because the common row driver DRC connected in common to the first pixel array PX1, the second pixel array PX2, and the third pixel array PX3 is provided, the size of the display device 100-4 may be reduced. In addition, because the first pixel array PX1, the second pixel array PX2, and the third pixel array PX3 are simultaneously controlled by the common row driver DRC, a separate circuit device for timing control of each of the first to third pixel arrays PX1, PX2, and PX3 may be omitted. Accordingly, the image quality of the display device 100-4 may be increased.

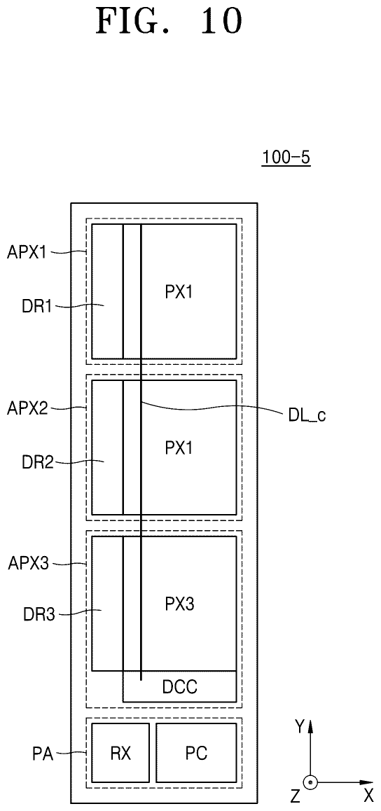

FIG. 10 is a schematic diagram of a display device 100-5 according to embodiments.

Referring to FIG. 10, the first pixel array region APX1, the second pixel array region APX2, and the third pixel array region APX3 may be arranged in line in the second horizontal direction Y. For example, the second pixel array region APX2 may be arranged between the first pixel array region APX1 and the third pixel array region APX3.

The column line DL_c may be connected in common to the first pixel array PX1, the second pixel array PX2, and the third pixel array PX3. A third pixel circuit unit may include the common column driver DCC electrically connected to the column line DL_c, which is connected in common to the first pixel array PX1, the second pixel array PX2, and the third pixel array PX3.

According to embodiments, because the common column driver DCC connected in common to the first pixel array PX1, the second pixel array PX2, and the third pixel array PX3 is provided, the size of the display device 100-5 may be reduced. In addition, because the first pixel array PX1, the second pixel array PX2, and the third pixel array PX3 are simultaneously controlled by the common column driver DCC, a separate circuit device for timing control of each of the first to third pixel arrays PX1, PX2, and PX3 may be omitted. Accordingly, the image quality of the display device 100-5 may be increased.

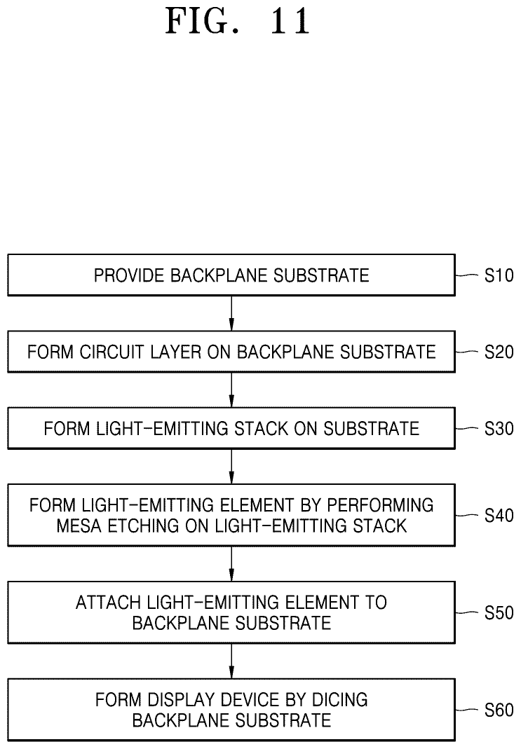

FIG. 11 is a flowchart of a method of manufacturing a display device, according to embodiments.

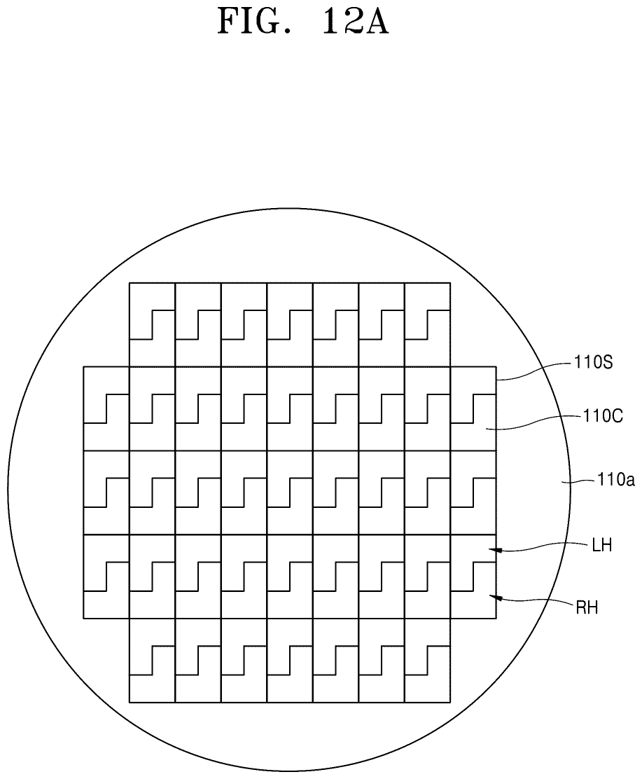

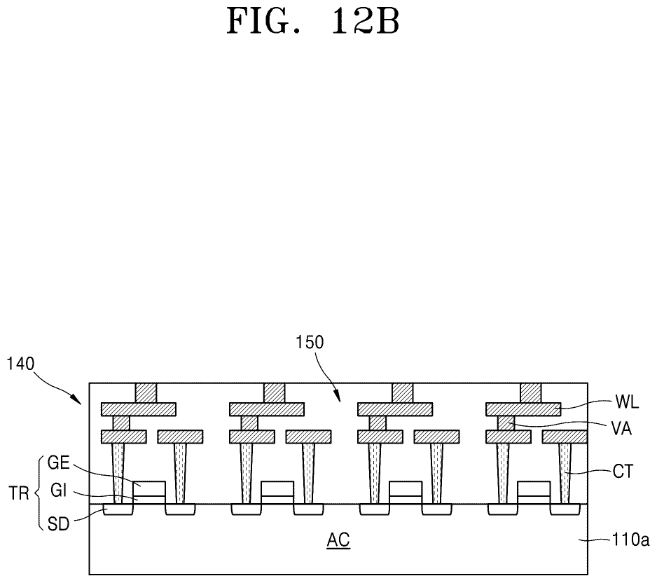

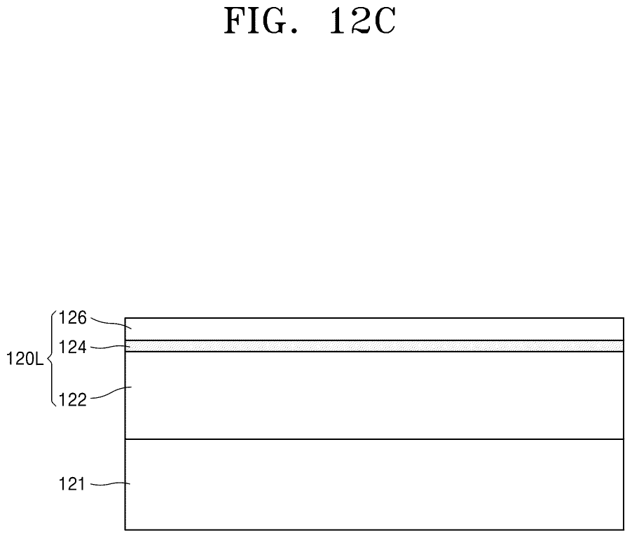

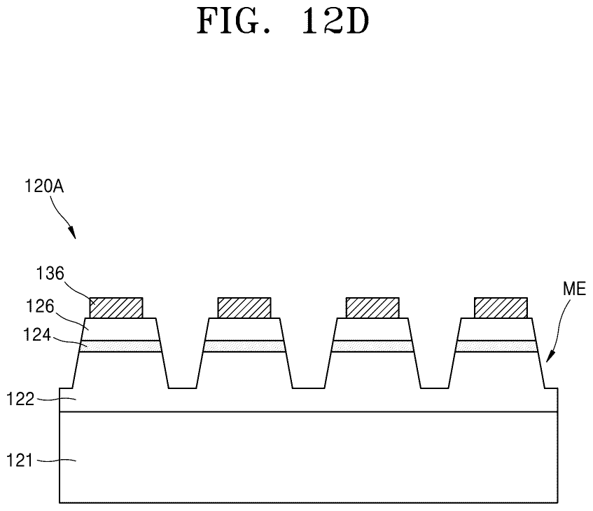

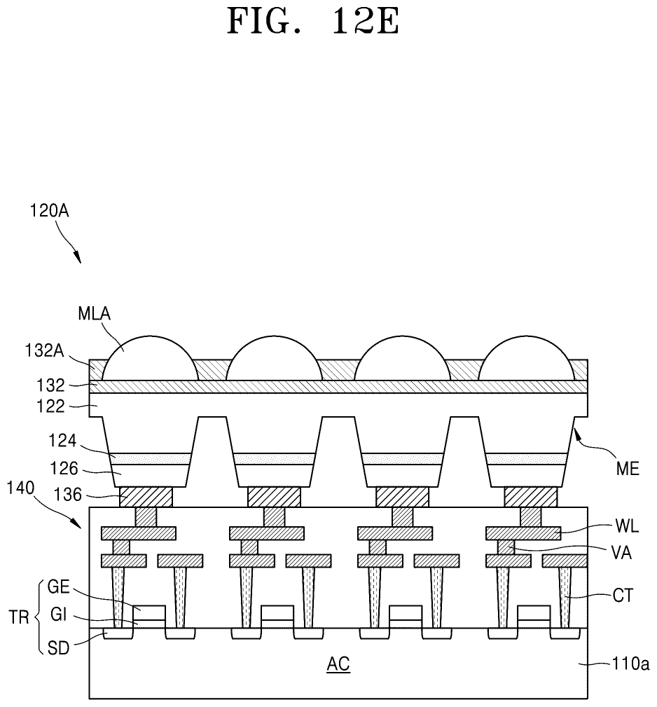

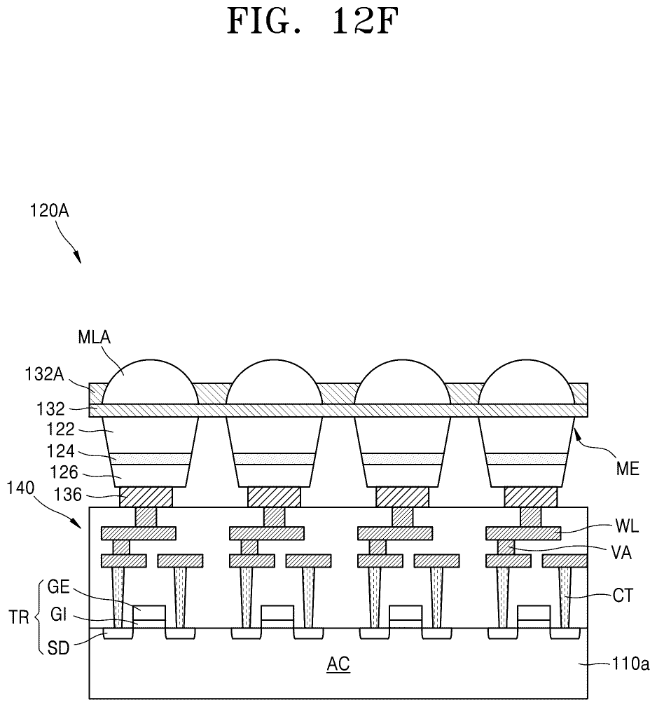

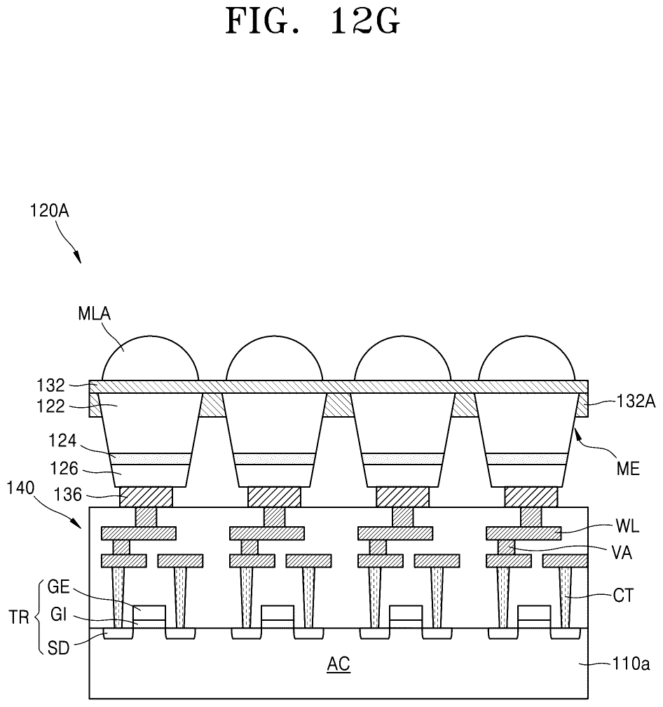

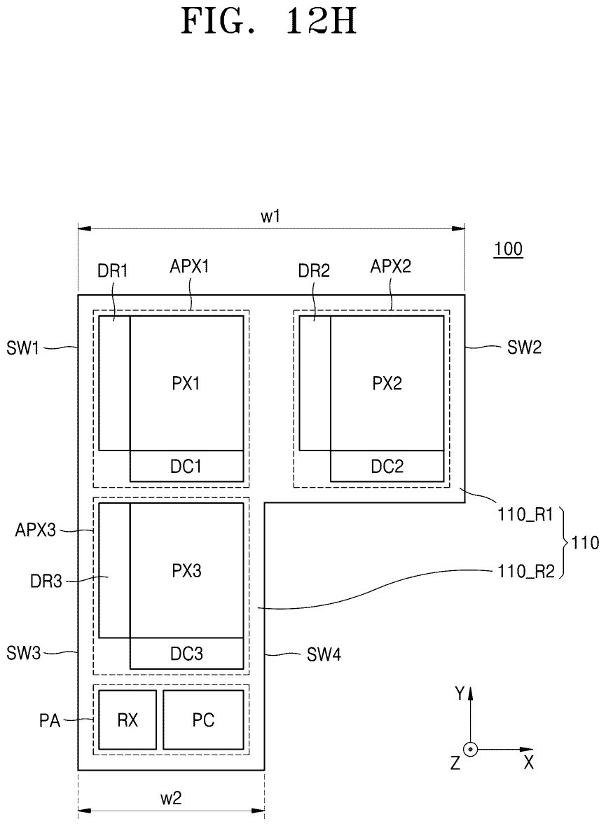

FIGS. 12A to 12H are schematic diagrams illustrating a method of manufacturing a display device, according to embodiments.

Referring to FIGS. 11 and 12A, a backplane substrate 110a may be provided in operation S10.

A plurality of chip regions 110C may be defined in the backplane substrate 110a. The backplane substrate 110a may be formed of a semiconductor material, and may be a silicon substrate, a germanium substrate, or a silicon germanium substrate, or a silicon-on-insulator (SOI) substrate. The chip regions 110C may be defined by a scribe lane 110S. Each of the chip regions 110C may be a portion of the backplane substrate 110a, in which the backplane 110 of one of the display devices 100, 100-1, 100-2, 100-3, 100-4, and 100-5 described with reference to FIGS. 1 to 10 may be formed. For example, each of the chip regions 110C may have a planar shape corresponding to the planar shape of the backplane 110 of one of the display devices 100, 100-1, 100-2, 100-3, 100-4, and 100-5 described with reference to FIGS. 1 to 10.

For example, each of the chip regions 110C may include a first chip region RH having an L-shaped horizontal cross-section (e.g., has an L shape from a plan view) and a second chip region LH having a shape in which the first chip region RH has rotated by 180 degrees. For example, the first chip region RH and the second chip region LH may collectively have a rectangular horizontal cross-section, and the chip regions 110C may be arranged without area loss of the backplane substrate 110a.

Referring to FIGS. 11 and 12B, a circuit layer 140 may be formed on the backplane substrate 110a in operation S20.

In embodiments, the circuit layer 140 may include various elements based on CMOS processes. For example, the circuit layer 140 may include active elements and passive elements, which form various types of circuits in the peripheral circuit region PA and the first to third pixel array regions APX1, APX2, and APX3, which are described with reference to FIG. 1. The circuit layer 140 may include transistors used for forming various types of circuits in the peripheral circuit region PA and the first to third pixel array regions APX1, APX2, and APX3. The transistors may be or include planar transistors, fin field-effect transistors, vertical channel transistors, metal gate transistors, negative charge transistors, gate-all-around type transistors, or a combinations thereof.

In some embodiments, the circuit layer 140 may include planar transistors TR. Each planar transistor TR may include a gate insulating layer GI arranged on an active region AC of the backplane substrate 110a, a gate electrode GE, and a source/drain region SD in the active region AC. The circuit layer 140 may be formed within an insulating layer 150.

In embodiments, the circuit layer 140 may further include at least one selected from the group consisting of a contact CT, a conductive via VA, a wiring line WL, and a through via structure, which connect various types of circuits in the peripheral circuit region PA and the first to third pixel array regions APX1, APX2, and APX3. Each of these components (contact CT, conductive via VA, wiring line WL, and through via structure) may be formed of an electrically conductive material, such as a metal, for example. Different of these components may be formed with different conductive materials. A contact CT may be a conductive vertical pillar passing through an insulating material of insulating layer 150 to connect an active region to a wiring line WL, a conductive via VA may be a vertically extending conductive component extending between two adjacent wiring lines WL, each wiring line WL may extend horizontally to connect two conductive vias VA formed at different vertical levels, and a through via structure may be a conductive pillar, for example, passing through the entire insulating layer to connect directly between a gate electrode GE or active region AC and a contact at or above a top surface of the insulating layer 150.

Referring to FIGS. 11 and 12C, a light-emitting stack 120L may be formed on the substrate 121 in operation S30. It should be noted that the steps shown in FIGS. 12C-12E may occur before, after, or at the same time, as the steps shown in FIGS. 12A and 12B.

In embodiments, the substrate 121 may be a transparent substrate such as sapphire. The light-emitting stack 120L may include the first conductivity-type semiconductor layer 122 on the top surface of the substrate 121, the active layer 124, and the second conductivity-type semiconductor layer 126.

In embodiments, the light-emitting stack 120L may be formed by an epitaxial growth process using the substrate 121 as a growth substrate. In the epitaxial growth process, a p-type dopant or an n-type dopant may be implanted into the light-emitting stack 120L.

Referring to FIGS. 11 and 12D, a light-emitting element 120A (e.g., a plurality of connected light emitting elements) may be formed by performing mesa etching on the light-emitting stack 120L in operation S40.

In embodiments, a process of performing mesa etching on the light-emitting stack 120L may include an etching process for partially removing the second conductivity-type semiconductor layer 126 and the active layer 124 and exposing the top surface of the first conductivity-type semiconductor layer 122. For example, a mesa region ME may be defined by the mesa etching. In some embodiments, the process of performing mesa etching on the light-emitting stack 120L may include, but is not limited to, a plasma etching process.

In some embodiments, after the mesa etching is performed on the light-emitting stack 120L, a passivation layer may be formed on the sidewall of the mesa region ME by using an insulating material such as silicon oxide.

In embodiments, the second electrode 136 may be formed on the top surface of the second conductivity-type semiconductor layer 126.

In some embodiments, the p-type contact layer may be or include, but is not limited to, a transparent electrode material such as indium tin oxide.

Referring to FIGS. 11 and 12E, a light-emitting element 120A (e.g., a plurality of connected light emitting elements) may be attached to the backplane substrate 110a in operation S50.

In embodiments, the light-emitting elements 120A may be attached to the backplane substrate 110a such that the second electrodes 136 are connected to the circuit layer 140. For example, the light-emitting elements 120A may be attached to the backplane substrate 110a such that an array of light-emitting elements 120A is arranged in the first to third pixel array regions APX1, APX2, and APX3 of the circuit layer 140. In embodiments, a transfer process and a bonding process may be performed to attach the light-emitting element 120A to the backplane substrate 110a.

Thereafter, the substrate 121 may be removed from the top surface of the light-emitting element 120A, and the first electrode 132 may be formed on the first conductivity-type semiconductor layer 122. The first electrode 132 may be formed using a transparent conductive material, such as indium tin oxide, gallium zinc oxide, zinc oxide, aluminum zinc oxide, or indium gallium zinc oxide. In some embodiments, before the first electrode 132 is formed on the top surface of the first conductivity-type semiconductor layer 122, a p-type contact layer may be formed on the top surface of the first conductivity-type semiconductor layer 122.

Thereafter, a microlens MLA array may be formed on the top surface of the light-emitting elements 120A. In some embodiments, a plurality of microlenses MLA may be formed in respective positions corresponding to a plurality of light-emitting elements 120A, for example, positions at which the microlenses MLA vertically overlap the light-emitting elements 120A, respectively.

In some embodiments, an electrode layer 132A may be arranged to surround the microlenses MLA in a plan view. The electrode layer 132A may be arranged on the top surface of the first electrode 132 and in contact with a lower sidewall of a microlens MLA and may have a lower height than the microlens MLA. In embodiments, the electrode layer 132A may include a metal material including at least one selected from the group consisting of Ag, Ni, Al, Cr, Rh, Pd, Ir, Ru, Mg, Zn, Pt, and Au. The electrode layer 132A may include or be formed of a reflective metal material or an opaque metal material and may have a higher conductivity than, for example, the first electrode 132.

FIG. 12F is a cross-sectional view of another embodiment. As shown in FIG. 12F, the electrode layer 132A may be arranged on the top surface of the first electrode 132 and in contact with a lower sidewall of the microlens MLA and may surround the microlens MLA in a plan view. Each of a plurality of light-emitting elements 120A may be physically apart from an adjacent light-emitting element 120A. For example, each of a plurality of light-emitting elements 120A may be apart from an adjacent light-emitting element 120A in a horizontal direction.

FIG. 12G is a cross-sectional view of still another embodiment. As shown in FIG. 12G, the electrode layer 132A may be arranged at a lower vertical level than the first electrode 132 and the microlens MLA and on the sidewall of each of a plurality of light-emitting elements 120A and may surround each of the light-emitting elements 120A in a plan view.

Referring to FIGS. 11 and 12H, the display device 100 may be formed by dicing the backplane substrate 110a in operation S60.

In embodiments, the display device 100 may be formed by dicing the backplane substrate 110a along the scribe lane 110S (see FIG. 12A). The backplane 110 may be formed by dicing the backplane substrate 110a, and the display device 100, in which the light-emitting elements 120A are attached to the first to third pixel array regions APX1, APX2, and APX3 of the backplane 110, may be obtained.

In embodiments, a process, such as blading, sawing, or plasma dicing, may be performed to dice the backplane substrate 110a. In some embodiments, when plasma dicing is used, the backplane 110 may have a hexagonal shape. In some embodiments, when plasma dicing is used, the backplane 110 may have a round corner.

In embodiments, as shown in FIG. 12H, the backplane 110 ma have an L-shaped horizontal cross-section. For example, the backplane 110 may include a first region 110_R1, which has a first width w1 in the first horizontal direction X parallel to the top surface of the backplane 110, and a second region 110_R2, which has a second width w2 in the first horizontal direction X. The second width w2 may range from about 40% to about 60% of the first width w1. In some embodiments, the second width w2 may range from about 45% to about 55% or about 48% to about 52% of the first width w1.

In embodiments, the first pixel array region APX1 and the second pixel array region APX2 may be arranged in the first region 110_R1, and the third pixel array region APX3 and the peripheral circuit region PA may be arranged in the second region 110_R2.

In embodiments, the first region 110_R1 may include a first side SW1 and a second side SW2 facing the first side SW1. The first side wall SW1 may extend the same distance in the second horizontal direction Y as the second sidewall SW2. The second region 110_R2 may include a third side SW3 and a fourth side SW4 facing the third side SW3. The third sidewall SW3 may extend the same distance in the second horizontal direction Y as the fourth sidewall SW4. The first side SW1 may be aligned in the second horizontal direction Y with the third side SW3. For example, the first side SW1 and the third side SW3 may be arranged on a straight line without a protrusion or an inflection point. The second side SW2 and the fourth side SW4 may not be aligned with each other in the second horizontal direction Y. A step may be formed between the second side SW2 and the fourth side SW4.

According to the embodiments described above, the circuit layer 140 may be formed on the backplane substrate 110a, the light-emitting element 120A may be attached to the circuit layer 140, and the display device 100 may be obtained by dicing the backplane substrate 110a.

As the first to third pixel arrays PX1, PX2, and PX3 and a drive circuit unit are arranged on the backplane 110 (e.g., both a circuit layer and the first to third pixel arrays PX1, PX2, and PX3 are formed on a backplane substrate 110a, to vertically overlap each other), the display device 100 may include only one integrated circuit (IC) chip (e.g., only one receiver interface RX). Accordingly, the display device 100 may operate at low power and have a compact size. In addition, because a package structure requiring a complex process for connecting a plurality of dies is not necessary, the manufacturing process of the display device 100 may be simplified.

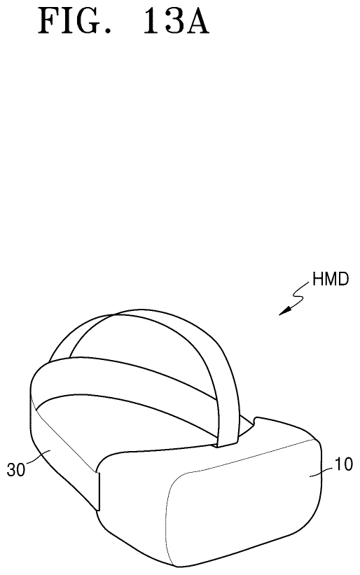

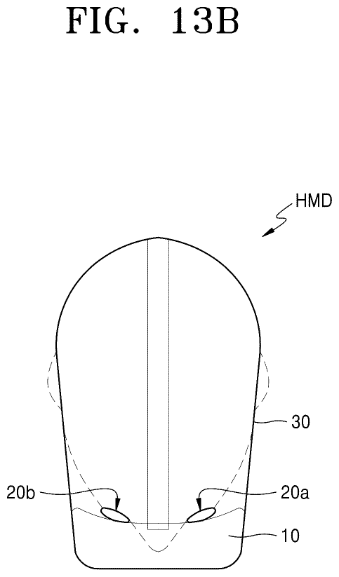

FIGS. 13A and 13B are schematic diagrams of a head-mounted display using a display device according to embodiments.

Referring to FIGS. 13 and 13B, a head-mounted display HMD using a display device (e.g., 100 of FIG. 1) according to embodiments may include a display accommodating case 10, a left eye lens 20a, a right eye lens 20b, and a head-mounted band 30. The head mounted display HMD may be goggles or glasses, for example.

The display accommodating case 10 may accommodate a display device and provide an image from the display device to the left eye lens 20a and the right eye lens 20b. The display device may include the display device 100 of FIG. 1 according to an embodiment.

The display accommodating case 10 may be designed to provide the same image to the left eye lens 20a and the right eye lens 20b. Alternatively, the display accommodating case 10 may be designed such that a left eye image is displayed on the left eye lens 20a and a right eye image is displayed on the right eye lens 20b. The structure of FIGS. 13A and 13B may be applied to VR, AR, and MR devices.

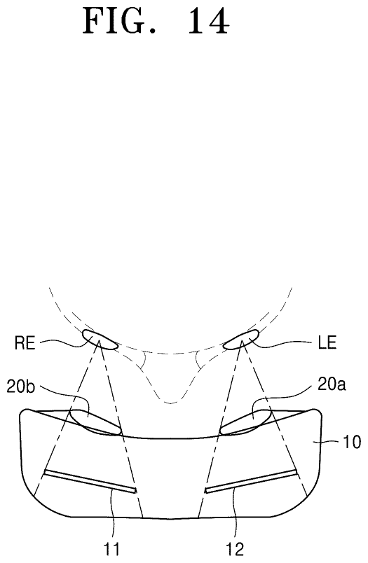

FIG. 14 is a schematic diagram of an example of the display-accommodating case 10 in FIGS. 13A and 13B.

FIG. 14 shows a cross-section of the display accommodating case 10 when viewed from above. A left-eye display device 11 may display a left eye image and a right-eye display device 12 may display a right-eye image. Accordingly, the left eye image displayed on the left-eye display device 11 may be shown to a user's left eye LE through the left eye lens 20a, and the right-eye image displayed on the right-eye display device 12 may be shown to a user's right eye RE through the right eye lens 20b.

In FIG. 14, a magnifying lens may be additionally arranged between the left eye lens 20a and the left-eye display device 11 and between the right eye lens 20b and the right-eye display device 12. In this case, due to the magnifying lens, an image displayed on each of the left-eye display device 11 and the right-eye display device 12 may be viewed by a user in an enlarged manner. The structure of FIG. 14 may be applied to VR, AR, and MR devices. Each of the left-eye display device 11 and the right-eye display device 12 may be one of the various display devices described in connection with FIGS. 1-12H.

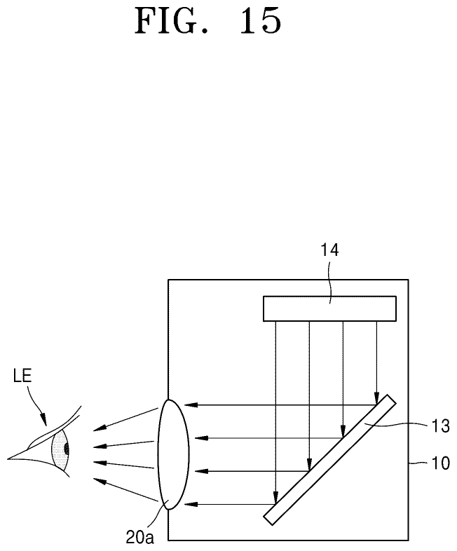

FIG. 15 is a schematic diagram of another example of the display-accommodating case 10 in FIGS. 13A and 13B.

FIG. 15 shows a cross-section of the display accommodating case 10 when viewed from a side. A display device 14 may display an image toward a mirror reflector 13, and the mirror reflector 13 may totally reflect the image from the display device 14 toward the left eye lens 20a and the right eye lens 20b. Accordingly, the image displayed on the display device 14 may be provided to the left eye lens 20a and the right eye lens 20b. For convenience of description, only the left eye lens 20a and the user's left eye LE are illustrated in FIG. 15. When the mirror reflector 13 is a half mirror as shown in FIG. 15, the display accommodating case 10 may be formed thin.

In FIG. 15, a magnifying lens may be additionally arranged between the left eye lens 20a and the mirror reflector 13 and between the right eye lens 20b and the mirror reflector 13. In this case, due to the magnifying lens, an image displayed on each of the left-eye display device 11 (see FIG. 14) and the right-eye display device 12 (see FIG. 14) may be viewed by a user in an enlarged manner. The display device 14 may be one of the various display devices described in connection with FIGS. 1-12H. The display-accommodating case 10 of FIG. 14 may be used, for example, for augmented reality head-mounted display.

Referring back to FIGS. 13A and 13B, the head-mounted band 30 may be fixed to the display accommodating case 10. The head-mounted band 30 may surround the top and both sides of a user's head, but embodiments are not limited thereto. The head-mounted band 30 may be used to secure the head-mounted display HMD to a user's head and may be formed as a glasses frame or a helmet.

According to a display device of the inventive concept, a first pixel array, a second pixel array, and a third pixel array may be arranged in or on a backplane, and a receiver interface, which receives image data and a control signal from an external host, may be arranged in or on a peripheral circuit region of the backplane (e.g., at the same vertical level as the first through third pixel arrays). Accordingly, power consumption for signal transfer between the external host and the first to third pixel arrays may be reduced, and the display device may have a simplified configuration and a compact size. Consequently, an electronic device capable of realizing low-power consumption and high-resolution image quality may be obtained.

While the inventive concept has been particularly shown and described with reference to embodiments thereof, it will be understood that various changes in form and details may be made therein without departing from the spirit and scope of the following claims.

What is claimed is:

1. A display device comprising:
a backplane including a first pixel array region, a second pixel array region, a third pixel array region, and a peripheral circuit region, each region horizontally separate from each other region;
a first pixel array arranged on the first pixel array region of the backplane;
a first pixel circuit unit arranged on the first pixel array region of the backplane and configured to drive the first pixel array;
a second pixel array arranged on the second pixel array region of the backplane;
a second pixel circuit unit arranged in the second pixel array region of the backplane and configured to drive the second pixel array;
a third pixel array arranged on the third pixel array region of the backplane;
a third pixel circuit unit arranged on the third pixel array region of the backplane and configured to drive the third pixel array; and
a drive circuit unit arranged on the peripheral circuit region of the backplane.

2. The display device of claim 1, wherein:
the first pixel array, second pixel array, third pixel array, first pixel circuit unit, second pixel circuit unit, third pixel circuit unit, and drive circuit are all disposed at the same level above a bottom surface of the backplane.

3. The display device of claim 1, wherein:
the drive circuit unit includes:
a receiver interface configured to receive image data and a control signal from an external host; and
a drive circuit configured to drive the first pixel circuit unit, the second pixel circuit unit, and the third pixel circuit unit, based on the image data and the control signal.

4. The display device of claim 1, wherein:
the first pixel array includes a plurality of first light-emitting elements arranged in a matrix and configured to emit light of a first wavelength,
the second pixel array includes a plurality of second light-emitting elements arranged in a matrix and configured to emit light of a second wavelength, and
the third pixel array includes a plurality of third light-emitting elements arranged in a matrix and configured to emit light of a third wavelength.

5. The display device of claim 1, wherein:
the first pixel circuit unit includes:
a first row driver electrically connected to a row line of the first pixel array and
a first column driver electrically connected to a column line of the first pixel array,
the second pixel circuit unit includes:
a second row driver electrically connected to a row line of the second pixel array and
a second column driver electrically connected to a column line of the second pixel array, and
the third pixel circuit unit includes:
a third row driver electrically connected to a row line of the third pixel array and
a third column driver electrically connected to a column line of the third pixel array.

6. The display device of claim 1, wherein:
the second pixel array region is adjacent to the first pixel array region in a horizontal direction that is parallel to a top surface of the backplane, and
the first pixel circuit unit includes:
a common row driver electrically connected in common to a row line of the first pixel array and a row line of the second pixel array.

7. The display device of claim 1, wherein:
the third pixel array region is adjacent to the first pixel array region in a horizontal direction that is parallel to a top surface of the backplane,
the third pixel circuit unit includes:
a common column driver electrically connected in common to a column line of the first pixel array and a column line of the third pixel array.

8. The display device of claim 1, wherein:
the second pixel array region is adjacent to the first pixel array region in a first horizontal direction that is parallel to a top surface of the backplane,
the third pixel array region is adjacent to the first pixel array region in a second horizontal direction that is parallel to the top surface of the backplane and crosses the first horizontal direction,
the first pixel circuit unit includes:
a common row driver electrically connected in common to a row line of the first pixel array and a row line of the second pixel array, and
the third pixel circuit unit includes:
a common column driver electrically connected in common to a column line of the first pixel array and a column line of the third pixel array.

9. The display device of claim 1, wherein:
the first pixel array region, the second pixel array region, and the third pixel array region are arranged in line in a horizontal direction that is parallel to a top surface of the backplane, and
the first pixel circuit unit includes:
a common row driver electrically connected in common to a row line of the first pixel array, a row line of the second pixel array, and a row line of the third pixel array.

10. The display device of claim 1, wherein:
the first pixel array region, the second pixel array region, and the third pixel array region are arranged in line in a horizontal direction that is parallel to a top surface of the backplane, and
the third pixel circuit unit includes:
a common column driver electrically connected in common to a column line of the first pixel array, a column line of the second pixel array, and a column line of the third pixel array.

11. The display device of claim 1, wherein the backplane includes a silicon substrate.

12. The display device of claim 1, wherein:
the backplane further includes:
a first region having a first width in a first horizontal direction that is parallel to a top surface of the backplane; and
a second region having a second width in the first horizontal direction,
the second width is between 40% and 60% of the first width,
the first pixel array region and the second pixel array region are arranged in the first region, and
the third pixel array region and the peripheral circuit region are arranged in the second region.

13. The display device of claim 12, wherein
the first region includes a first side and a second side opposite the first side,
the second region includes a third side and a fourth side opposite the third side, and
the first side is aligned with the third side.

14. The display device of claim 13, wherein the backplane has an L shape in a plan view.

15. The display device of claim 12, further comprising a pad in the peripheral circuit region.

16. The display device of claim 1, wherein the display device is a display portion of a head-mounted display.

17. A display device comprising:
a backplane including a first pixel array region, a second pixel array region, a third pixel array region, and a peripheral circuit region;
a first pixel array arranged on the first pixel array region of the backplane and including a plurality of first light-emitting elements arranged in a matrix;
a second pixel array arranged on the second pixel array region of the backplane and including a plurality of second light-emitting elements arranged in a matrix;
a third pixel array arranged on the third pixel array region of the backplane and including a plurality of third light-emitting elements arranged in a matrix; and
a drive circuit unit arranged on the peripheral circuit region of the backplane, wherein the drive circuit unit includes:
a receiver interface configured to receive image data and a control signal from an external host; and
a drive circuit configured to drive the first pixel array, the second pixel array, and the third pixel array, based on the image data and the control signal.

18. The display device of claim 17, further comprising:
a first pixel circuit unit arranged on the first pixel array region of the backplane and configured to drive the first pixel array based on the image data and the control signal that are received from the drive circuit;
a second pixel circuit unit arranged on the second pixel array region of the backplane and configured to drive the second pixel array based on the image data and the control signal that are received from the drive circuit; and
a third pixel circuit unit arranged on the third pixel array region of the backplane and configured to drive the third pixel array based on the image data and the control signal that are received from the drive circuit.

19. The display device of claim 18, wherein:
the first pixel circuit unit, the second pixel circuit unit, and the third pixel circuit unit each include a complementary metal-oxide semiconductor (CMOS) transistor or a thin-film transistor.

20. An electronic device comprising:
a host processor; and
a display system connected to the host processor,
wherein the display system includes:
a backplane including a first pixel array region, a second pixel array region, a third pixel array region, and a peripheral circuit region;
a first pixel array arranged on the first pixel array region of the backplane and including a plurality of first light-emitting elements arranged in a matrix;
a second pixel array arranged on the second pixel array region of the backplane and including a plurality of second light-emitting elements arranged in a matrix;
a third pixel array arranged on the third pixel array region of the backplane and including a plurality of third light-emitting elements arranged in a matrix; and
a drive circuit unit arranged on the peripheral circuit region of the backplane, wherein the drive circuit unit includes:
a receiver interface configured to receive image data and a control signal from the host processor; and
a drive circuit configured to drive the first pixel array, the second pixel array, and the third pixel array, based on the image data and the control signal.
